(19) United States
(12) Patent Application Publication
(10) Pub. No.: US 2010/0033942 A1
(43) Pub. Date: Feb. 11, 2010

(54) SUPPORTING STRUCTURE AND ELECTRONIC DEVICE USING THE SAME

(76) Inventors: CHIH-CHING YANG, Taipei City (TW); SHU-FANG CHUEH, Taipei City (TW)

Correspondence Address: KAMRATH & ASSOCIATES P.A., 4825 OLSON MEMORIAL HIGHWAY, SUITE 245, GOLDEN VALLEY, MN, 55422, US

(21) Appl. No.: 12/534,923

(22) Filed: Aug. 4, 2009

(30) Foreign Application Priority Data
Aug. 7, 2008 (TW) 097130089

(51) Int. Cl. H05K 7/04

(52) U.S. Cl. 361/809

(57) ABSTRACT

A supporting structure for a circuit board includes a main body, a first post, and a second post. One end of the first post is connected to the main body, and the cross-sectional diameter of the first post is less than that of the main body. The second post is connected to the other end of the first post, and the cross-sectional diameter of the second post is less than that of the first post. The supporting structure is correspondingly inserted into a corresponding hole on the circuit board.

### CROSS-REFERENCE TO RELATED APPLICATIONS

This Non-provisional application claims priority under 35 U.S.C. §119(a) on Patent Application No(s). 097130089 filed in Taiwan, Republic of China on Aug. 7, 2008, the entire contents of which are hereby incorporated by reference.

### BACKGROUND OF THE INVENTION

1. Field of the Invention

The invention relates to a supporting structure and, more particularly, to a supporting structure capable of adjusting height in which it is disposed according to corresponding holes having different diameters on a circuit board.

2. Description of the Related Art

Supporting elements are often used to support or space the circuit board and the components in a screwed mode or an engaged mode for preventing contact or collision between the components in an interior of an electronic device. For a notebook computer, since the internal space of the notebook computer is limited, parts of the components, such as an additional disposed daughter card, a mini PCI expansion card, a modem daughter card, or any other structural members need to be parallel to and overlap a motherboard of the notebook computer to decrease the occupied space. A plurality of supporting elements need to be used to support, fasten, or connect the motherboard and the components in the notebook computer.

Since different components or boards have different thickness and corresponding slots are disposed in different heights, the supporting elements in accordance with respective specification should be used on the motherboard. Therefore, the height of each component can be adjusted for fastening securely. Once the components increases, more supporting elements with different specifications may be used. Thus, the assembling time and cost of the electronic device may increase.

### BRIEF SUMMARY OF THE INVENTION

The invention provides a supporting structure capable of adjusting height that it provides according to corresponding holes having different diameters on a circuit board to solve the problem that the supporting structures with different specifications need to be used for supporting different components.

The embodiment of the supporting structure in the invention includes a main body, a first post, and a second post. One end of the first post is connected to the main body, and the cross-sectional diameter of the first post is less than that of the main body. The second post is connected to the other end of the first post, and the cross-sectional diameter of the second post is less than that of the first post. The supporting structure is inserted into a corresponding hole on the circuit board to adjust height that the supporting structure provides.

The embodiment of the electronic device in the invention includes a circuit board, at least one component, and at least one supporting structure described above. The supporting structure fastens the component. The component is supported on the circuit board by at least one supporting structure for connecting or fastening the component and the circuit board. The height that the supporting structure providing is adjusted according to the specification of each component by inserting into corresponding holes disposed on the circuit board.

According to different sizes of the corresponding holes on the circuit board, the same supporting structure provides different heights when inserted into the corresponding holes, thereby assembling or connecting different components and decreasing the assembling cost and time.

These and other features, aspects, and advantages of the present invention will become better understood with regard to the following description, appended claims, and accompanying drawings.

### BRIEF DESCRIPTION OF THE DRAWINGS

FIG. 1 is a three-dimensional diagram showing a supporting structure according to a preferred embodiment of the invention;

FIG. 2 is a sectional schematic diagram showing the supporting structure along a sectional line C-C′ in FIG. 1 according to a preferred embodiment of the invention;

FIG. 3 is a bottom view showing a supporting structure according to a preferred embodiment of the invention;

FIG. 4A and FIG. 4B are schematic diagrams showing different using states of a supporting structure according to a preferred embodiment of the invention;

FIG. 5A and FIG. 5B are schematic diagrams showing combining states of a supporting structure and a component according to a preferred embodiment of the invention; and

FIG. 6 is a schematic diagram showing an electronic device according to a preferred embodiment of the invention.

### DETAILED DESCRIPTION OF THE INVENTION

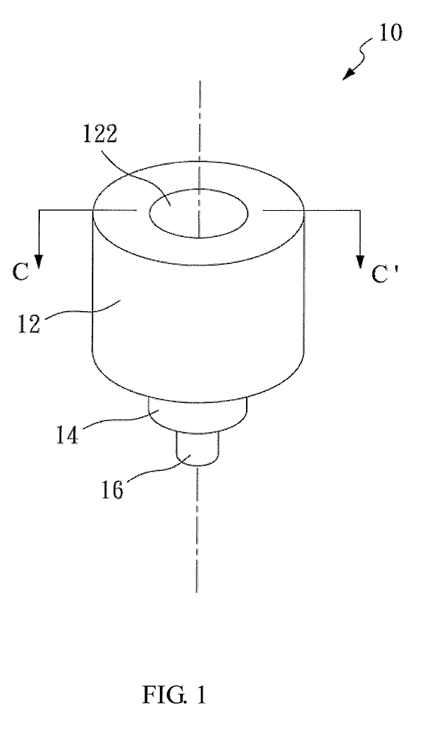

FIG. 1 is a three-dimensional diagram showing a supporting structure 10 according to a preferred embodiment of the invention. In FIG. 1, the supporting structure 10 includes a main body 12, a first post 14, and a second post 16. In one embodiment of the invention, the main body 12, the first post 14, and the second post 16 are cylinders. However, they may be cubes, prisms, or post with any other shapes. The invention is not limited thereto. One end of the first post 14 is connected to the main body 12, and the second post 16 is connected to the other end of the first post 14. The supporting structure 10 includes a fastening structure 122 disposed at the end of the main body 12 opposite to the end connected to the first post 14. The fastening structure 122 is used for providing a fastening effect.

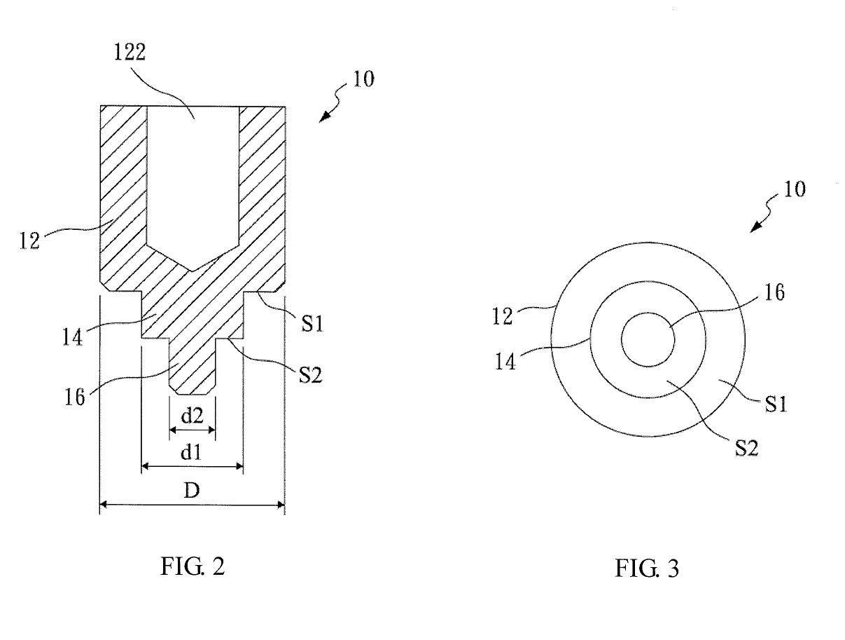

FIG. 2 is a sectional schematic diagram showing the supporting structure 10 along a sectional line C-C′ in FIG. 1 according to a preferred embodiment of the invention. FIG. 3 is a bottom view showing the supporting structure 10 according to a preferred embodiment of the invention. In FIG. 2 and FIG. 3, the main body 12, the first post 14, and the second post 16 of the supporting structure 10 in the embodiment are coaxially connected cylinders. The cross-sectional diameter d1 of the first post 14 is less than the cross-sectional diameter D of the main body 12. Thus, the surface of the main body 12 except the part that the first post 14 connected is a first supporting surface S1. The cross-sectional diameter d2 of the second post 16 is less than the cross-sectional diameter d1 of the first post 14. Thus, the surface of the first post 14 except the part that the second post 16 connected is a second supporting surface S2.

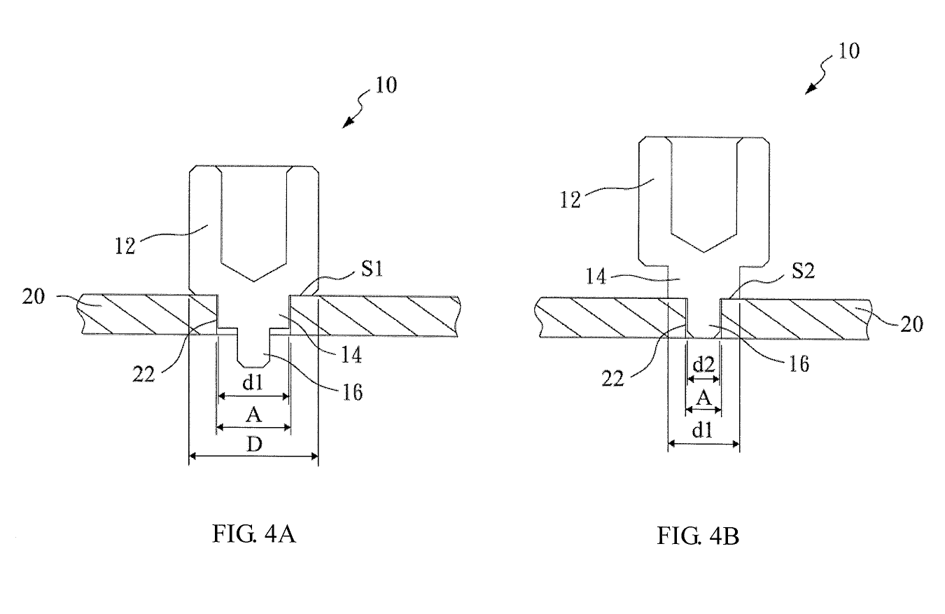

FIG. 4A and FIG. 4B are schematic diagrams showing different using states of the supporting structure 10 according to a preferred embodiment of the invention. In FIG. 4A, the supporting structure 10 in the embodiment is applied to a circuit board 20. The circuit board 20 has corresponding holes 22 with different diameters. A diameter A of the corresponding hole 22 is determined in cooperation with the supporting structure 10. When the diameter A of the corresponding hole 22 is greater than or equal to the cross-sectional diameter d1 of the first post 14 and is less than the cross-sectional diameter D of the main body 12, the corresponding hole 22 allows the first post 14 of the supporting structure 10 to be inserted. At that moment, the supporting structure 10 is against the circuit board 20 by the first supporting surface S1 of the main body 12. In FIG. 4B, when the diameter A of the corresponding hole 22 is greater than or equal to the cross-sectional diameter d2 of the second post 16 and is less than the cross-sectional diameter d1 of the first post 14, the corresponding hole 22 only allows the second post 16 of the supporting structure 10 to be inserted. At that moment, the supporting structure 10 is against the circuit board 20 by the second supporting surface S2 of the first post 14. Thereby, the first post 14 or the second post 16 of the supporting structure 10 can be correspondingly inserted into the corresponding holes 22 having different diameters A on the circuit board 20. Thus, the supporting structure 10 provides different heights to match different components. The heights of the main body 12, the first post 14, and the second post 16 can change for different design needs or different applicable devices. In addition, in one embodiment of the invention, the supporting structure 10 forms a two-stage height adjusting design by the first post 14 and the second post 16 to cooperate with the corresponding hole 22 of the circuit board 20. However, the invention is not limited thereto. Additional post structures can be added on the second post 16 according to needs, thus to allow the supporting structure 10 to cooperate with the corresponding holes 22 for a three-stage or multi-stage height adjusting.

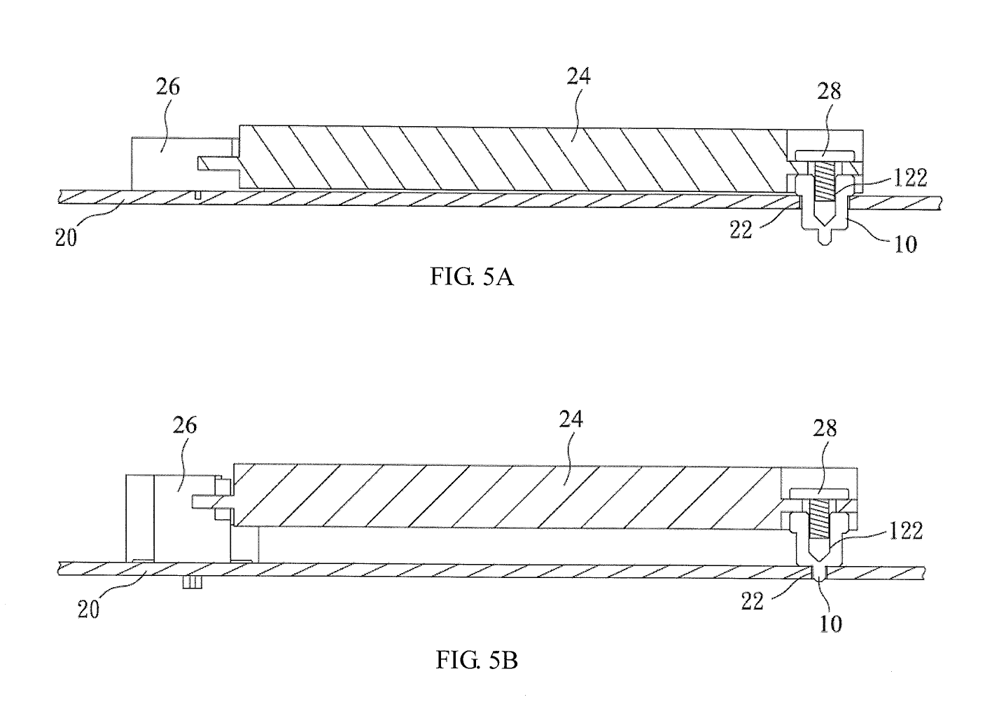

FIG. 5A and FIG. 5B are schematic diagrams showing combining states of the supporting structure 10 and a component 24 according to a preferred embodiment of the invention. In FIG. 5A and FIG. 5B, according to the components 24 with different specification on the circuit board 20, the height that the supporting structure 10 provides is adjusted. In one embodiment of the invention, the component 24 is a mini PCI expansion card. When the mini PCI expansion card is inserted into a corresponding slot 26 on the circuit board 20, the height of the corresponding slot 26 may be different in different designs of the circuit board 20. The height that the supporting structure 10 provides may be different to correspond to the component 24. The fastening structure 122 of the supporting structure 10 fastens the component 24. In one embodiment of the invention, the fastening structure 122 is a screw hole capable of cooperating with a screw 28 to fasten the component 24. However, an engaged mode or other fastening modes may be used. In addition, the component 24 may be a modem daughter card, a circuit board, any other electronic components, or any other structural members, to cooperate with the supporting structure 10. However, the invention is not limited thereto.

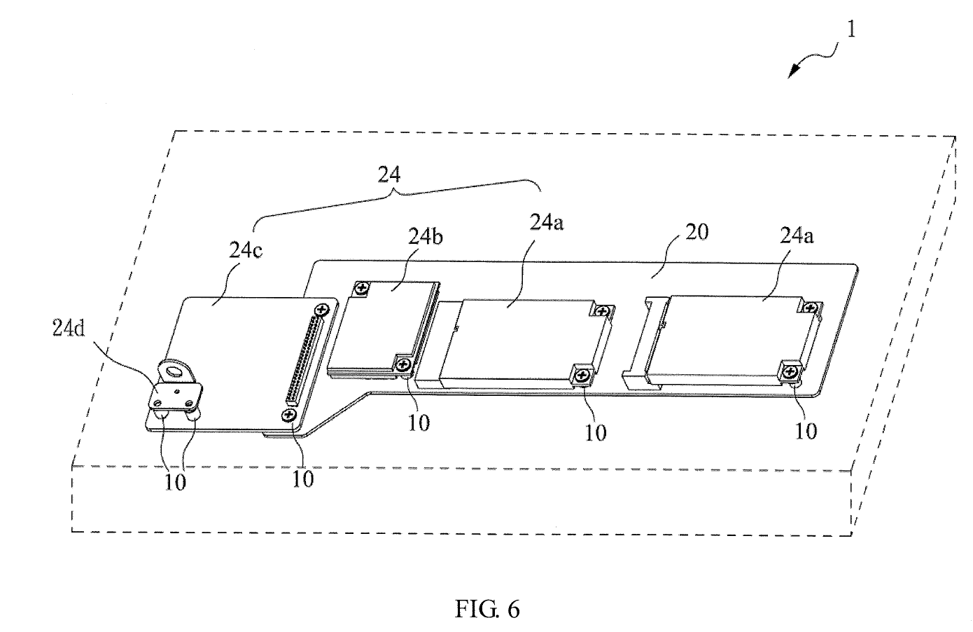

FIG. 6 is a schematic diagram showing an electronic device 1 according to a preferred embodiment of the invention. In FIG. 6, the electronic device 1 includes a circuit board 20, at least one component 24, and at least one supporting structure 10 described above. In one embodiment of the invention, the electronic device 1 is a notebook computer. The component 24 may include a mini PCI expansion card 24a, a modem daughter card 24b, a circuit board 24c, a structural member 24d, or any other electronic components. The supporting structure 10 may be used to fasten the component 24. Each component 24 is supported and connected on the circuit board 20 by at least one supporting structure 10. The height that the at least one supporting structure 10 provides is adjusted according to the specification of each component 24 by the corresponding holes (not shown) on the circuit board 20. In addition, any electronic device 1 including a circuit board may use the structure in the invention. The electronic device 1 may be a PDA, a GPS, or any other computer devices. The invention is not limited thereto.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A supporting structure for a circuit board, the supporting structure comprising:
a main body;
a first post having one end connected to the main body, the cross-sectional diameter of the first post being less than that of the main body; and
a second post connected to the other end of the first post, the cross-sectional diameter of the second post being less than that of the first post,
wherein the supporting structure capable of being correspondingly inserted into a corresponding hole on the circuit board.

2. The supporting structure according to claim 1, wherein when a diameter of the corresponding hole is greater than or equal to the cross-sectional diameter of the first post and is less than the cross-sectional diameter of the main body, the supporting structure is against the circuit board by the main body.

3. The supporting structure according to claim 1, wherein when a diameter of the corresponding hole is greater than or equal to the cross-sectional diameter of the second post and is less than the cross-sectional diameter of the first post, the supporting structure is against the circuit board by the first post.

4. The supporting structure according to claim 1, further comprising a fastening structure disposed at the main body to fasten a component.

5. The supporting structure according to claim 4, wherein the fastening structure fastens the component in a screwed mode or an engaged mode.

6. The supporting structure according to claim 4, wherein the component is a mini PCI expansion card, a modem daughter card, a circuit board, or a structural member.

7. The supporting structure according to claim 1, wherein the main body, the first post, and the second post are coaxially connected cylinders.

8. An electronic device comprising:
a circuit board;
at least one supporting structure capable of being correspondingly inserted into a corresponding hole on the circuit board, wherein each supporting structure includes:
a main body;
a first post having one end connected to the main body, the cross-sectional diameter of the first post being less than that of the main body;
a second post connected to the other end of the first post, the cross-sectional diameter of the second post being less than that of the first post; and
at least one component fastened by the supporting structure, the component supported on the circuit board by the supporting structure.

9. The electronic device according to claim 8, wherein when a diameter of the corresponding hole is greater than or equal to the cross-sectional diameter of the first post and is less than the cross-sectional diameter of the main body, the supporting structure is against the circuit board via the main body.

10. The electronic device according to claim 8, wherein when a diameter of the corresponding hole is greater than or equal to the cross-sectional diameter of the second post and is less than the cross-sectional diameter of the first post, the supporting structure is against the circuit board via the first post.

11. The electronic device according to claim 8, further comprising a fastening structure disposed at the main body to fasten the component.

12. The electronic device according to claim 11, wherein the fastening structure fastens the component in a screwed mode or an engaged mode.

13. The electronic device according to claim 11, wherein the component is a mini PCI expansion card, a modem daughter card, a circuit board, or a structural member.

14. The electronic device according to claim 8, wherein the electronic device is a notebook computer.

15. The electronic device according to claim 8, wherein the main body, the first post, and the second post are coaxially connected cylinders.
